(19) United States
(12) Patent Application Publication
(10) Pub. No.: US 2025/0130119 A1
(43) Pub. Date: Apr. 24, 2025

(54) TEMPERATURE DETECTION CIRCUIT AND METHOD, ELECTRONIC DEVICE, AND COMPUTER-READABLE STORAGE MEDIUM

(71) Applicant: Luxshare Precision Industry Company Limited, SHENZHEN (CN)

(72) Inventor: Kai LIANG, SHENZHEN (CN)

(73) Assignee: Luxshare Precision Industry Company Limited, SHENZHEN (CN)

(21) Appl. No.: 18/911,073

(22) Filed: Oct. 9, 2024

(30) Foreign Application Priority Data
Oct. 18, 2023 (CN) 202311352077.0

(51) Int. Cl. G01K 7/20; G01K 15/00

(52) U.S. Cl. CPC G01K 7/20; G01K 15/005

(57) ABSTRACT

The present application relates to a temperature detection circuit and method, an electronic device, and a computer-readable storage medium. The temperature detection circuit includes: a temperature detection module, configured to charge a charging module based on a detected temperature; a timing module, configured to detect the voltage of the charging module to determine a charging rate of the temperature detection module, generate a first time signal corresponding to the charging rate, and send the first time signal to the processing module; and a processing module, configured to determine a target temperature value through the first time signal. The temperature detection module is configured to charge the charging module based on the detected temperature, so that the charging rate can quickly reflect the detected temperature, which ensures the rate of temperature detection. Meanwhile, the charging rate can accurately match the target temperature value corresponding to the current temperature.

### CROSS-REFERENCE TO RELATED APPLICATION

This non-provisional application claims priority claim under 35 U.S.C. § 119 (a) on Chinese Patent Application No. 202311352077.0 filed Oct. 18, 2023, the entire contents of which are hereby incorporated by reference.

### TECHNICAL FIELD

The present application relates to the field of temperature detection, in particular to a temperature detection circuit and method, an electronic device, and a computer-readable storage medium.

### BACKGROUND

In existing technologies, the body temperature is often detected by a mercury meter or an electronic probe. However, the mercury meter outputs values slowly, and the electronic probe has low precision. Therefore, existing body temperature detection methods cannot achieve high speed and accuracy simultaneously.

### SUMMARY

The present application provides a temperature detection circuit and method, an electronic device, and a computer-readable storage medium, in order to solve the technical problem in the existing technologies that the precision cannot be guaranteed while values are output quickly in body temperature monitoring.

In a first aspect, the present application provides a temperature detection circuit, including a charging module, a temperature detection module, a timing module, and a processing module, where the charging module is coupled to detection terminals of the temperature detection module and the timing module respectively, and an output terminal of the timing module is coupled to the processing module, where the temperature detection module is configured to charge the charging module based on a detected temperature;
the timing module is configured to detect the voltage of the charging module to determine a charging rate of the temperature detection module, generate a first time signal corresponding to the charging rate, and send the first time signal to the processing module; and
the processing module is configured to determine a target temperature value through the first time signal.

Optionally, the temperature detection module includes a temperature-sensitive resistor, a first terminal of the temperature-sensitive resistor is coupled to a first port of the processing module, and a second terminal of the temperature-sensitive resistor is coupled to the charging module.

Optionally, the charging module includes a calibration unit and a first capacitor,
a first terminal of the first capacitor is coupled to the detection terminals of the calibration unit, the temperature detection module, and the timing module respectively, and a second terminal of the first capacitor is grounded; and
the calibration unit is configured to charge the first capacitor at a preset charging rate.

Optionally, the calibration unit includes a first resistor, where
a first terminal of the first resistor is coupled to a second port of the processing module, and a second terminal of the first resistor is coupled to the first terminal of the first capacitor; and
the first resistor is a non-temperature-sensitive resistor.

Optionally, the timing module includes an operational amplifier, a second resistor, a third resistor, and a fourth resistor, where
an inverting input terminal of the operational amplifier is coupled to the charging module, a non-inverting input terminal of the operational amplifier is grounded through the second resistor, the non-inverting input terminal of the operational amplifier is also coupled to a third port of the processing module through the third resistor, and an output terminal of the operational amplifier serves as the output terminal of the timing module; a first terminal of the fourth resistor is coupled to the output terminal of the operational amplifier, and a second terminal of the fourth resistor is coupled between the second resistor and the third resistor.

In a second aspect, the present invention further provides a temperature detection method, which is applied to the body temperature monitoring circuit as described above; the temperature detection method includes:
sending a first charging signal to the temperature detection module, so that the temperature detection module charges the charging module;
receiving a first time signal sent by the timing module, where the first time signal is generated based on a charging rate of the temperature detection module, and the charging rate is obtained by detecting the voltage of the charging module; and
determining a target temperature value through the first time signal.

Optionally, the step of receiving a first time signal sent by the timing module includes:
activating a timer for timing when sending the first charging signal to the temperature detection module;
stopping the timer when receiving a low-level signal sent by the operational amplifier, to obtain timing duration; and
designating the timing duration as the first time signal.

Optionally, the step of determining a target temperature value through the first time signal includes:
matching a first temperature value corresponding to the first time signal;
obtaining a second temperature value and calculating a change slope between the second temperature value and the first temperature value, where the second temperature value is the first temperature value matched last time;
determining whether the change slope is less than or equal to a preset slope threshold; and
designating the first temperature value as the target temperature value if the change slope is less than or equal to the preset slope threshold.

Optionally, after the step of determining whether the change slope is less than a preset slope threshold, the method includes:
outputting a ground signal to the first port to discharge the first capacitor if the change slope is greater than the preset slope threshold; and
performing the step of sending a first charging signal to the temperature detection module after the discharging of the first capacitor is completed.

Optionally, the performing the step of sending a first charging signal to the temperature detection module after the discharging of the first capacitor is completed includes:
matching a delay time corresponding to the change slope, where the larger the change slope, the shorter the delay time; and
performing the step of sending a first charging signal to the temperature detection module after the discharging of the first capacitor is completed and the discharging completion time reaches the delay time.

Optionally, if the change slope is greater than the preset slope threshold, the method further includes:
matching a predicted temperature compensation value corresponding to the slope change;
designating a sum of the predicted temperature compensation value and the first temperature value as a current predicted value; and
outputting the current predicted value.

Optionally, before the step of sending a first charging signal to the temperature detection module, the method further includes:
sending a second charging signal to the first resistor to charge the first capacitor;
receiving a second time signal sent by the timing module;
determining whether the second time signal is consistent with a preset calibration time; and
performing a warning operation if the second time signal is inconsistent with the preset calibration time; or
performing the step of sending a first charging signal to the temperature detection module if the second time signal is consistent with the preset calibration time.

In a third aspect, the present invention further provides an electronic device, including a memory, a processor, and a computer program stored in the memory and executable on the processor, where the computer program, when executed by the processor, implements the steps of the temperature detection method as described above.

In a fourth aspect, the present invention further provides a computer-readable storage medium, storing a computer program that, when executed by a processor, implements the steps of the temperature detection method as described above.

The present invention provides a temperature detection circuit and method, an electronic device, and a computer-readable storage medium. The temperature detection circuit includes a charging module, a temperature detection module, a timing module, and a processing module, where the charging module is coupled to detection terminals of the temperature detection module and the timing module respectively, and an output terminal of the timing module is coupled to the processing module; the temperature detection module is configured to charge the charging module based on a detected temperature; the timing module is configured to detect the voltage of the charging module to determine a charging rate of the temperature detection module, generate a first time signal corresponding to the charging rate, and send the first time signal to the processing module; and the processing module is configured to determine a target temperature value through the first time signal. The temperature detection module is configured to charge the charging module based on the detected temperature, so that the charging rate can quickly reflect the detected temperature, which ensures the rate of temperature detection. Meanwhile, the charging rate can accurately match the target temperature value corresponding to the current temperature.

### BRIEF DESCRIPTION OF THE DRAWINGS

The accompanying drawings herein are incorporated into the description and constitute a portion of the description, show embodiments consistent with the present invention, and are used together with the description for explaining the principle of the present invention.

In order to describe the technical solutions in the embodiments of the present invention or in the prior art more clearly, the following briefly introduces the accompanying drawings required for use in the description of the embodiments or the prior art. Apparently, those of ordinary skill in the art can derive other drawings from the accompanying drawings without any creative effort.

FIG. 1 is a schematic diagram of modules of a temperature detection circuit in the present invention;

FIG. 2 is a specific structural diagram of the temperature detection circuit in the present invention;

FIG. 3 is a schematic diagram of an output format of a target temperature value in a temperature detection method of the present invention;

FIG. 4 is a schematic diagram of an overall process of the temperature detection method in the present invention; and

FIG. 5 is a schematic diagram of a module structure of an electronic device in the present invention.

### DESCRIPTION OF REFERENCE NUMERALS

| Numeral | Name | Numeral | Name |
|---|---|---|---|
| 100 | Charging module | R1-R5 | First resistor-Fifth resistor |
| 110 | Calibration unit | C1-C3 | First capacitor-Third |
| | | | capacitor |
| 200 | Temperature | RT | Temperature-sensitive |
| | detection module | | resistor |
| 300 | Timing module | U1 | Operational amplifier |
| 400 | Processing module | GPIO1 | First port |
| GPIO2 | Second port | GPIO3 | Third port |

### DETAILED DESCRIPTION

It should be understood that the specific embodiments described herein are merely used for interpreting the present invention, rather than limiting the present invention. To make those skilled in the art understand the technical solutions in the present application better, the following clearly and completely describes the technical solutions in the embodiments of the present application with reference to the accompanying drawings therein. Apparently, the described embodiments are merely some rather than all of the embodiments of the present application. Based on the embodiments in the present application, all other embodiments obtained by those of ordinary skill in the art without any creative effort shall fall within the scope of protection of the present application.

The present invention provides a temperature detection circuit, including a charging module 100, a temperature detection module 200, a timing module 300, and a processing module 400. The charging module 100 is coupled to detection terminals of the temperature detection module 200 and the timing module 300 respectively, and an output terminal of the timing module 300 is coupled to the processing module 400.

The temperature detection module 200 is configured to charge the charging module 100 based on a detected temperature.

The timing module 300 is configured to detect the voltage of the charging module 100 to determine a charging rate of the temperature detection module 200, generate a first time signal corresponding to the charging rate, and send the first time signal to the processing module 400.

The processing module 400 is configured to determine a target temperature value through the first time signal.

The temperature detection module 200 detects the ambient temperature to determine the charging rate. Different ambient temperatures correspond to different charging rates, and the charging module 100 is charged at the charging rate. As the charging progresses, the voltage of the charging module 100 continues to rise; the timing module 300 detects the voltage of the charging module 100 to determine a rise rate of the voltage of the charging module 100 and then to determine the charging rate of the temperature detection module 200 based on the rise rate, generates the first time signal corresponding to the charging rate, and sends the first time signal to the processing module 400; and the processing module 400 determines the target temperature value based on the first time signal.

The target temperature value is a temperature value of a temperature detection object.

In this embodiment, the temperature detection module 200 is configured to charge the charging module 100 based on the detected temperature, so that the charging rate can quickly reflect the detected temperature, which ensures the rate of temperature detection. Meanwhile, the charging rate can accurately match the target temperature value corresponding to the current temperature.

Further, with reference to FIG. 2, the temperature detection module 200 includes a temperature-sensitive resistor RT, a first terminal of the temperature-sensitive resistor RT is coupled to a first port GPIO1 of the processing module 400, and a second terminal of the temperature-sensitive resistor RT is coupled to the charging module 100.

The temperature-sensitive resistor RT has different resistance values based on different temperatures. Notably, the specific type and resistance range of the temperature-sensitive resistor RT can be set based on actual application needs. For example, the temperature-sensitive resistor RT may have a positive temperature coefficient or a negative temperature coefficient. The temperature-sensitive resistor RT having the negative temperature coefficient NTC is taken as an example for explanation in this embodiment, and the temperature-sensitive resistor RT having the positive temperature coefficient PTC can be analogically set.

The temperature-sensitive resistor RT is coupled in series between the charging module 100 and the first port GPIO1 of the processing module 400; when the first port GPO1 is powered on, the voltage at the first port GPO1 charges the charging module 100 through the temperature-sensitive resistor RT; and when the first port GPIO1 is grounded, the charging module 100 is discharged through the temperature-sensitive resistor RT. Notably, in this embodiment, a GPIO (General-purpose input/output) interface configured in the processing module 400 is used as the first port GPO1, and the processing module 400 switches the output voltage to achieve power-on, power-off, or grounding of the first port GPO1. In other embodiments, the first terminal of the temperature-sensitive resistor RT may be coupled to a power supply or the ground through a switch, and the switch is controlled to achieve power-on, power-off, or grounding. The second port GPO2 and the third port GPO3 below are similar and will not be repeated.

The temperature detection module 200 further includes a second capacitor C2 and a third capacitor C3, the second terminal of the temperature-sensitive resistor RT is grounded through the second capacitor C2, and the first terminal of the temperature-sensitive resistor RT is grounded through the third capacitor C3.

The second capacitor C2 and the third capacitor C3 are ESD capacitors, which are configured to release electrostatic energy in the circuit, so as to ensure the stability of the circuit.

Further, the charging module 100 includes a calibration unit 110 and a first capacitor C1, a first terminal of the first capacitor C1 is coupled to the detection terminals of the calibration unit 110, the temperature detection module 200, and the timing module 300 respectively, and a second terminal of the first capacitor C1 is grounded.

The calibration unit 110 is configured to charge the first capacitor C1 at a preset charging rate.

The calibration unit 110 is configured to calibrate the state of the first capacitor C1. The calibration unit 110 calibrates the first capacitor C1 through the preset charging rate, and the capacitance value of the first capacitor C1 remains unchanged under normal circumstances. Therefore, the charging rate of the first capacitor C1 remains consistent at the preset charging rate. When the actual charging rate of the first capacitor C1 is inconsistent with the preset charging rate, it indicates that the first capacitor C1 is faulty, such as being damaged and unable to charge, and decreasing in capacitance value due to aging. In this case, relevant measures, such as warning or compensation, need to be taken to avoid testing accuracy problems caused by the fault of the first capacitor C1.

The first capacitor C1 is charged when the temperature detection module 200 or the calibration unit 110 is powered on, and discharged when the temperature detection module 200 or the calibration unit 110 is grounded. From the above explanation, it can be seen that the capacitance value of the first capacitor C1 has a decisive impact on the determination of the target temperature value. Therefore, in order to ensure the accuracy of detection, the capacitance value of the first capacitor C1 should be kept stable. In this embodiment, a temperature-insensitive capacitor is configured as the first capacitor C1, such as being made of an NPO or COG material, to ensure the stability of the first capacitor C1.

Refer to the table below for a comparison of the duration ΔT when the voltage of the first capacitor C1 rises from 0 to the non-inverting input terminal voltage of the operational amplifier U1, the temperature, and the resistance value of the temperature-sensitive resistor RT in an application scenario when the first capacitor C1 is 0.1 μF, where NTCmin indicates a minimum resistance value of the temperature-sensitive resistor RT in the corresponding situation; NTCnor indicates a general resistance value of the temperature-sensitive resistor RT in the corresponding situation; and NTCmax indicates a maximum resistance value of the temperature-sensitive resistor RT in the corresponding situation;

| | | | | NTCmin | NTCnor | NTCmax | | |
|---|---|---|---|---|---|---|---|---|
| ΔT | | | Unit | (kΩ) | (kΩ) | (kΩ) | Temperature | Unit |
| 2.3535 | 2.3558 | 2.3574 | ms | 33.954 | 33.987 | 34.010 | 34.00 | ° C. |
| 2.3487 | 2.3510 | 2.3526 | ms | 33.885 | 33.918 | 33.941 | 34.05 | ° C. |
| 2.3439 | 2.3462 | 2.3478 | ms | 33.816 | 33.849 | 33.872 | 34.10 | ° C. |
| 2.3392 | 2.3415 | 2.3430 | ms | 33.747 | 33.780 | 33.803 | 34.15 | ° C. |
| 2.3344 | 2.3367 | 2.3383 | ms | 33.678 | 33.711 | 33.734 | 34.20 | ° C. |
| 2.3296 | 2.3319 | 2.3335 | ms | 33.609 | 33.642 | 33.665 | 34.25 | ° C. |
| 2.3248 | 2.3271 | 2.3287 | ms | 33.540 | 33.573 | 33.596 | 34.30 | ° C. |
| 2.3200 | 2.3223 | 2.3239 | ms | 33.471 | 33.504 | 33.527 | 34.35 | ° C. |
| 2.3153 | 2.3175 | 2.3191 | ms | 33.402 | 33.435 | 33.458 | 34.40 | ° C. |
| 2.3105 | 2.3128 | 2.3143 | ms | 33.333 | 33.366 | 33.389 | 34.45 | ° C. |
| 2.3057 | 2.3080 | 2.3096 | ms | 33.264 | 33.297 | 33.320 | 34.50 | ° C. |
| 2.3009 | 2.3032 | 2.3048 | ms | 33.195 | 33.228 | 33.251 | 34.55 | ° C. |
| 2.2961 | 2.2984 | 2.3000 | ms | 33.126 | 33.159 | 33.182 | 34.60 | ° C. |
| 2.2913 | 2.2936 | 2.2952 | ms | 33.057 | 33.090 | 33.113 | 34.65 | ° C. |
| 2.2866 | 2.2888 | 2.2904 | ms | 32.988 | 33.021 | 33.044 | 34.70 | ° C. |
| 2.2818 | 2.2841 | 2.2857 | ms | 32.919 | 32.952 | 32.975 | 34.75 | ° C. |
| 2.2770 | 2.2793 | 2.2809 | ms | 32.850 | 32.883 | 32.906 | 34.80 | ° C. |
| 2.2722 | 2.2745 | 2.2761 | ms | 32.781 | 32.814 | 32.837 | 34.85 | ° C. |
| 2.2674 | 2.2697 | 2.2713 | ms | 32.712 | 32.745 | 32.768 | 34.90 | ° C. |
| 2.2626 | 2.2649 | 2.2665 | ms | 32.643 | 32.676 | 32.699 | 34.95 | ° C. |
| 2.2570 | 2.2596 | 2.2614 | ms | 32.562 | 32.599 | 32.625 | 35.00 | ° C. |
| 2.2526 | 2.2550 | 2.2568 | ms | 32.498 | 32.533 | 32.559 | 35.05 | ° C. |
| 2.2482 | 2.2504 | 2.2522 | ms | 32.434 | 32.467 | 32.493 | 35.10 | ° C. |
| 2.2437 | 2.2458 | 2.2476 | ms | 32.370 | 32.401 | 32.427 | 35.15 | ° C. |
| 2.2393 | 2.2413 | 2.2431 | ms | 32.306 | 32.335 | 32.361 | 35.20 | ° C. |
| 2.2348 | 2.2367 | 2.2385 | ms | 32.242 | 32.269 | 32.295 | 35.25 | ° C. |
| 2.2304 | 2.2321 | 2.2339 | ms | 32.178 | 32.202 | 32.228 | 35.30 | ° C. |
| 2.2260 | 2.2275 | 2.2293 | ms | 32.114 | 32.136 | 32.162 | 35.35 | ° C. |
| 2.2215 | 2.2229 | 2.2247 | ms | 32.050 | 32.070 | 32.096 | 35.40 | ° C. |
| 2.2171 | 2.2184 | 2.2202 | ms | 31.986 | 32.004 | 32.030 | 35.45 | ° C. |
| 2.2127 | 2.2138 | 2.2156 | ms | 31.922 | 31.938 | 31.964 | 35.50 | ° C. |
| 2.2082 | 2.2092 | 2.2110 | ms | 31.858 | 31.872 | 31.898 | 35.55 | ° C. |
| 2.2038 | 2.2046 | 2.2064 | ms | 31.794 | 31.806 | 31.832 | 35.60 | ° C. |
| 2.1994 | 2.2000 | 2.2018 | ms | 31.730 | 31.740 | 31.766 | 35.65 | ° C. |
| 2.1949 | 2.1954 | 2.1972 | ms | 31.666 | 31.674 | 31.700 | 35.70 | ° C. |
| 2.1905 | 2.1909 | 2.1927 | ms | 31.602 | 31.608 | 31.634 | 35.75 | ° C. |
| 2.1860 | 2.1863 | 2.1881 | ms | 31.538 | 31.541 | 31.567 | 35.80 | ° C. |
| 2.1816 | 2.1817 | 2.1835 | ms | 31.474 | 31.475 | 31.501 | 35.85 | ° C. |
| 2.1772 | 2.1771 | 2.1789 | ms | 31.410 | 31.409 | 31.435 | 35.90 | ° C. |
| 2.1727 | 2.1725 | 2.1743 | ms | 31.346 | 31.343 | 31.369 | 35.95 | ° C. |
| 2.1657 | 2.1679 | 2.1700 | ms | 31.245 | 31.276 | 31.307 | 36.00 | ° C. |
| 2.1614 | 2.1635 | 2.1657 | ms | 31.182 | 31.213 | 31.244 | 36.05 | ° C. |
| 2.1570 | 2.1592 | 2.1613 | ms | 31.119 | 31.150 | 31.181 | 36.10 | ° C. |
| 2.1527 | 2.1548 | 2.1570 | ms | 31.056 | 31.087 | 31.118 | 36.15 | ° C. |
| 2.1483 | 2.1505 | 2.1526 | ms | 30.994 | 31.025 | 31.056 | 36.20 | ° C. |
| 2.1440 | 2.1461 | 2.1483 | ms | 30.931 | 30.962 | 30.993 | 36.25 | ° C. |
| 2.1396 | 2.1417 | 2.1439 | ms | 30.868 | 30.899 | 30.930 | 36.30 | ° C. |
| 2.1352 | 2.1374 | 2.1395 | ms | 30.805 | 30.836 | 30.867 | 36.35 | ° C. |
| 2.1309 | 2.1330 | 2.1352 | ms | 30.742 | 30.773 | 30.804 | 36.40 | ° C. |
| 2.1265 | 2.1287 | 2.1308 | ms | 30.679 | 30.710 | 30.741 | 36.45 | ° C. |
| 2.1222 | 2.1243 | 2.1265 | ms | 30.617 | 30.648 | 30.679 | 36.50 | ° C. |
| 2.1178 | 2.1200 | 2.1221 | ms | 30.554 | 30.585 | 30.616 | 36.55 | ° C. |
| 2.1135 | 2.1156 | 2.1178 | ms | 30.491 | 30.522 | 30.553 | 36.60 | ° C. |
| 2.1091 | 2.1113 | 2.1134 | ms | 30.428 | 30.459 | 30.490 | 36.65 | ° C. |
| 2.1047 | 2.1069 | 2.1090 | ms | 30.365 | 30.396 | 30.427 | 36.70 | ° C. |
| 2.1004 | 2.1025 | 2.1047 | ms | 30.302 | 30.333 | 30.364 | 36.75 | ° C. |
| 2.0960 | 2.0982 | 2.1003 | ms | 30.239 | 30.270 | 30.301 | 36.80 | ° C. |
| 2.0917 | 2.0938 | 2.0960 | ms | 30.177 | 30.208 | 30.239 | 36.85 | ° C. |
| 2.0873 | 2.0895 | 2.0916 | ms | 30.114 | 30.145 | 30.176 | 36.90 | ° C. |
| 2.0830 | 2.0851 | 2.0873 | ms | 30.051 | 30.082 | 30.113 | 36.95 | ° C. |
| 2.0789 | 2.0794 | 2.0826 | ms | 29.992 | 30.000 | 30.045 | 37.00 | ° C. |
| 2.0747 | 2.0753 | 2.0784 | ms | 29.932 | 29.940 | 29.985 | 37.05 | ° C. |
| 2.0705 | 2.0711 | 2.0742 | ms | 29.871 | 29.879 | 29.924 | 37.10 | ° C. |
| 2.0663 | 2.0669 | 2.0700 | ms | 29.811 | 29.819 | 29.864 | 37.15 | ° C. |
| 2.0621 | 2.0627 | 2.0658 | ms | 29.750 | 29.758 | 29.803 | 37.20 | ° C. |
| 2.0580 | 2.0585 | 2.0616 | ms | 29.690 | 29.698 | 29.743 | 37.25 | ° C. |
| 2.0538 | 2.0543 | 2.0574 | ms | 29.630 | 29.638 | 29.683 | 37.30 | ° C. |
| 2.0496 | 2.0501 | 2.0533 | ms | 29.569 | 29.577 | 29.622 | 37.35 | ° C. |
| 2.0454 | 2.0459 | 2.0491 | ms | 29.509 | 29.517 | 29.562 | 37.40 | ° C. |
| 2.0412 | 2.0418 | 2.0449 | ms | 29.448 | 29.456 | 29.501 | 37.45 | ° C. |
| 2.0370 | 2.0376 | 2.0407 | ms | 29.388 | 29.396 | 29.441 | 37.50 | ° C. |
| 2.0328 | 2.0334 | 2.0365 | ms | 29.328 | 29.336 | 29.381 | 37.55 | ° C. |
| 2.0286 | 2.0292 | 2.0323 | ms | 29.267 | 29.275 | 29.320 | 37.60 | ° C. |
| 2.0245 | 2.0250 | 2.0281 | ms | 29.207 | 29.215 | 29.260 | 37.65 | ° C. |
| 2.0203 | 2.0208 | 2.0239 | ms | 29.146 | 29.154 | 29.199 | 37.70 | ° C. |
| 2.0161 | 2.0166 | 2.0198 | ms | 29.086 | 29.094 | 29.139 | 37.75 | ° C. |
| 2.0119 | 2.0125 | 2.0156 | ms | 29.026 | 29.034 | 29.079 | 37.80 | ° C. |
| 2.0077 | 2.0083 | 2.0114 | ms | 28.965 | 28.973 | 29.018 | 37.85 | ° C. |
| 2.0035 | 2.0041 | 2.0072 | ms | 28.905 | 28.913 | 28.958 | 37.90 | ° C. |
| 1.9993 | 1.9999 | 2.0030 | ms | 28.844 | 28.852 | 28.897 | 37.95 | ° C. |
| 1.9950 | 1.9970 | 1.9990 | ms | 28.782 | 28.811 | 28.839 | 38.00 | ° C. |
| 1.9910 | 1.9930 | 1.9950 | ms | 28.725 | 28.754 | 28.782 | 38.05 | ° C. |
| 1.9871 | 1.9891 | 1.9910 | ms | 28.667 | 28.696 | 28.724 | 38.10 | ° C. |
| 1.9831 | 1.9851 | 1.9870 | ms | 28.610 | 28.639 | 28.667 | 38.15 | ° C. |
| 1.9791 | 1.9811 | 1.9830 | ms | 28.552 | 28.581 | 28.609 | 38.20 | ° C. |
| 1.9751 | 1.9771 | 1.9791 | ms | 28.495 | 28.524 | 28.552 | 38.25 | ° C. |
| 1.9711 | 1.9731 | 1.9751 | ms | 28.437 | 28.466 | 28.494 | 38.30 | ° C. |
| 1.9671 | 1.9692 | 1.9711 | ms | 28.380 | 28.409 | 28.437 | 38.35 | ° C. |
| 1.9632 | 1.9652 | 1.9671 | ms | 28.322 | 28.351 | 28.379 | 38.40 | ° C. |
| 1.9592 | 1.9612 | 1.9631 | ms | 28.265 | 28.294 | 28.322 | 38.45 | ° C. |
| 1.9552 | 1.9572 | 1.9591 | ms | 28.208 | 28.237 | 28.265 | 38.50 | ° C. |
| 1.9512 | 1.9532 | 1.9552 | ms | 28.150 | 28.179 | 28.207 | 38.55 | ° C. |
| 1.9472 | 1.9492 | 1.9512 | ms | 28.093 | 28.122 | 28.150 | 38.60 | ° C. |
| 1.9432 | 1.9453 | 1.9472 | ms | 28.035 | 28.064 | 28.092 | 38.65 | ° C. |
| 1.9393 | 1.9413 | 1.9432 | ms | 27.978 | 28.007 | 28.035 | 38.70 | ° C. |
| 1.9353 | 1.9373 | 1.9392 | ms | 27.920 | 27.949 | 27.977 | 38.75 | ° C. |
| 1.9313 | 1.9333 | 1.9353 | ms | 27.863 | 27.892 | 27.920 | 38.80 | ° C. |
| 1.9273 | 1.9293 | 1.9313 | ms | 27.805 | 27.834 | 27.862 | 38.85 | ° C. |
| 1.9233 | 1.9253 | 1.9273 | ms | 27.748 | 27.777 | 27.805 | 38.90 | ° C. |
| 1.9194 | 1.9214 | 1.9233 | ms | 27.690 | 27.719 | 27.747 | 38.95 | ° C. |
| 1.9152 | 1.9174 | 1.9192 | ms | 27.631 | 27.662 | 27.688 | 39.00 | ° C. |
| 1.9114 | 1.9136 | 1.9151 | ms | 27.576 | 27.607 | 27.629 | 39.05 | ° C. |
| 1.9076 | 1.9098 | 1.9111 | ms | 27.522 | 27.553 | 27.572 | 39.10 | ° C. |
| 1.9039 | 1.9060 | 1.9072 | ms | 27.467 | 27.498 | 27.515 | 39.15 | ° C. |
| 1.9001 | 1.9022 | 1.9032 | ms | 27.412 | 27.443 | 27.458 | 39.20 | ° C. |
| 1.8963 | 1.8984 | 1.8993 | ms | 27.357 | 27.388 | 27.401 | 39.25 | ° C. |
| 1.8925 | 1.8946 | 1.8953 | ms | 27.303 | 27.334 | 27.344 | 39.30 | ° C. |
| 1.8887 | 1.8908 | 1.8914 | ms | 27.248 | 27.279 | 27.287 | 39.35 | ° C. |
| 1.8849 | 1.8870 | 1.8874 | ms | 27.193 | 27.224 | 27.230 | 39.40 | ° C. |
| 1.8811 | 1.8832 | 1.8835 | ms | 27.138 | 27.169 | 27.173 | 39.45 | ° C. |
| 1.8773 | 1.8794 | 1.8795 | ms | 27.084 | 27.115 | 27.116 | 39.50 | ° C. |
| 1.8735 | 1.8756 | 1.8756 | ms | 27.029 | 27.060 | 27.059 | 39.55 | ° C. |
| 1.8697 | 1.8718 | 1.8716 | ms | 26.974 | 27.005 | 27.002 | 39.60 | ° C. |
| 1.8659 | 1.8680 | 1.8677 | ms | 26.919 | 26.950 | 26.945 | 39.65 | ° C. |
| 1.8621 | 1.8643 | 1.8637 | ms | 26.865 | 26.896 | 26.888 | 39.70 | ° C. |
| 1.8583 | 1.8605 | 1.8598 | ms | 26.810 | 26.841 | 26.831 | 39.75 | ° C. |
| 1.8545 | 1.8567 | 1.8558 | ms | 26.755 | 26.786 | 26.774 | 39.80 | ° C. |
| 1.8507 | 1.8529 | 1.8519 | ms | 26.700 | 26.731 | 26.717 | 39.85 | ° C. |
| 1.8469 | 1.8491 | 1.8479 | ms | 26.646 | 26.677 | 26.660 | 39.90 | ° C. |
| 1.8431 | 1.8453 | 1.8440 | ms | 26.591 | 26.622 | 26.603 | 39.95 | ° C. |
| 1.8392 | 1.8415 | 1.8427 | ms | 26.534 | 26.567 | 26.585 | 40.00 | ° C. |
| 1.8356 | 1.8379 | 1.8391 | ms | 26.482 | 26.515 | 26.533 | 40.05 | ° C. |
| 1.8319 | 1.8342 | 1.8355 | ms | 26.429 | 26.462 | 26.480 | 40.10 | ° C. |
| 1.8283 | 1.8306 | 1.8319 | ms | 26.377 | 26.410 | 26.428 | 40.15 | ° C. |
| 1.8247 | 1.8270 | 1.8282 | ms | 26.325 | 26.358 | 26.376 | 40.20 | ° C. |
| 1.8211 | 1.8234 | 1.8246 | ms | 26.273 | 26.306 | 26.324 | 40.25 | ° C. |
| 1.8174 | 1.8197 | 1.8210 | ms | 26.220 | 26.253 | 26.271 | 40.30 | ° C. |
| 1.8138 | 1.8161 | 1.8174 | ms | 26.168 | 26.201 | 26.219 | 40.35 | ° C. |
| 1.8102 | 1.8125 | 1.8137 | ms | 26.116 | 26.149 | 26.167 | 40.40 | ° C. |
| 1.8066 | 1.8089 | 1.8101 | ms | 26.063 | 26.096 | 26.114 | 40.45 | ° C. |
| 1.8029 | 1.8052 | 1.8065 | ms | 26.011 | 26.044 | 26.062 | 40.50 | ° C. |
| 1.7993 | 1.8016 | 1.8029 | ms | 25.959 | 25.992 | 26.010 | 40.55 | ° C. |
| 1.7957 | 1.7980 | 1.7992 | ms | 25.906 | 25.939 | 25.957 | 40.60 | ° C. |
| 1.7921 | 1.7944 | 1.7956 | ms | 25.854 | 25.887 | 25.905 | 40.65 | ° C. |
| 1.7884 | 1.7907 | 1.7920 | ms | 25.802 | 25.835 | 25.853 | 40.70 | ° C. |
| 1.7848 | 1.7871 | 1.7884 | ms | 25.750 | 25.783 | 25.801 | 40.75 | ° C. |
| 1.7812 | 1.7835 | 1.7847 | ms | 25.697 | 25.730 | 25.748 | 40.80 | ° C. |
| 1.7776 | 1.7799 | 1.7811 | ms | 25.645 | 25.678 | 25.696 | 40.85 | ° C. |
| 1.7739 | 1.7762 | 1.7775 | ms | 25.593 | 25.626 | 25.644 | 40.90 | ° C. |
| 1.7703 | 1.7726 | 1.7739 | ms | 25.540 | 25.573 | 25.591 | 40.95 | ° C. |
| 1.7666 | 1.7683 | 1.7700 | ms | 25.486 | 25.511 | 25.535 | 41.00 | ° C. |
| 1.7631 | 1.7649 | 1.7665 | ms | 25.437 | 25.462 | 25.486 | 41.05 | ° C. |
| 1.7597 | 1.7614 | 1.7631 | ms | 25.387 | 25.412 | 25.436 | 41.10 | ° C. |
| 1.7563 | 1.7580 | 1.7597 | ms | 25.338 | 25.363 | 25.387 | 41.15 | ° C. |
| 1.7529 | 1.7546 | 1.7563 | ms | 25.288 | 25.313 | 25.337 | 41.20 | ° C. |
| 1.7494 | 1.7512 | 1.7528 | ms | 25.239 | 25.264 | 25.288 | 41.25 | ° C. |
| 1.7460 | 1.7477 | 1.7494 | ms | 25.190 | 25.215 | 25.239 | 41.30 | ° C. |
| 1.7426 | 1.7443 | 1.7460 | ms | 25.140 | 25.165 | 25.189 | 41.35 | ° C. |
| 1.7392 | 1.7409 | 1.7426 | ms | 25.091 | 25.116 | 25.140 | 41.40 | ° C. |
| 1.7357 | 1.7375 | 1.7391 | ms | 25.041 | 25.066 | 25.090 | 41.45 | ° C. |
| 1.7323 | 1.7340 | 1.7357 | ms | 24.992 | 25.017 | 25.041 | 41.50 | ° C. |
| 1.7289 | 1.7306 | 1.7323 | ms | 24.943 | 24.968 | 24.992 | 41.55 | ° C. |
| 1.7255 | 1.7272 | 1.7289 | ms | 24.893 | 24.918 | 24.942 | 41.60 | ° C. |
| 1.7220 | 1.7238 | 1.7254 | ms | 24.844 | 24.869 | 24.893 | 41.65 | ° C. |
| 1.7186 | 1.7203 | 1.7220 | ms | 24.794 | 24.819 | 24.843 | 41.70 | ° C. |
| 1.7152 | 1.7169 | 1.7186 | ms | 24.745 | 24.770 | 24.794 | 41.75 | ° C. |
| 1.7118 | 1.7135 | 1.7152 | ms | 24.696 | 24.721 | 24.745 | 41.80 | ° C. |
| 1.7083 | 1.7101 | 1.7117 | ms | 24.646 | 24.671 | 24.695 | 41.85 | ° C. |
| 1.7049 | 1.7067 | 1.7083 | ms | 24.597 | 24.622 | 24.646 | 41.90 | ° C. |
| 1.7015 | 1.7032 | 1.7049 | ms | 24.547 | 24.572 | 24.596 | 41.95 | ° C. |
| 1.6980 | 1.6998 | 1.7010 | ms | 24.497 | 24.523 | 24.540 | 42.00 | ° C. |
| 1.6946 | 1.6964 | 1.6976 | ms | 24.448 | 24.474 | 24.491 | 42.05 | ° C. |
| 1.6913 | 1.6931 | 1.6942 | ms | 24.400 | 24.426 | 24.443 | 42.10 | ° C. |
| 1.6879 | 1.6897 | 1.6909 | ms | 24.351 | 24.377 | 24.394 | 42.15 | ° C. |
| 1.6845 | 1.6863 | 1.6875 | ms | 24.302 | 24.328 | 24.345 | 42.20 | ° C. |
| 1.6811 | 1.6829 | 1.6841 | ms | 24.254 | 24.280 | 24.297 | 42.25 | ° C. |
| 1.6777 | 1.6796 | 1.6807 | ms | 24.205 | 24.231 | 24.248 | 42.30 | ° C. |
| 1.6744 | 1.6762 | 1.6774 | ms | 24.156 | 24.182 | 24.199 | 42.35 | ° C. |
| 1.6710 | 1.6728 | 1.6740 | ms | 24.107 | 24.133 | 24.150 | 42.40 | ° C. |
| 1.6676 | 1.6694 | 1.6706 | ms | 24.059 | 24.085 | 24.102 | 42.45 | ° C. |
| 1.6642 | 1.6660 | 1.6672 | ms | 24.010 | 24.036 | 24.053 | 42.50 | ° C. |
| 1.6609 | 1.6627 | 1.6639 | ms | 23.961 | 23.987 | 24.004 | 42.55 | ° C. |
| 1.6575 | 1.6593 | 1.6605 | ms | 23.913 | 23.939 | 23.956 | 42.60 | ° C. |
| 1.6541 | 1.6559 | 1.6571 | ms | 23.864 | 23.890 | 23.907 | 42.65 | ° C. |
| 1.6507 | 1.6525 | 1.6537 | ms | 23.815 | 23.841 | 23.858 | 42.70 | ° C. |
| 1.6474 | 1.6492 | 1.6503 | ms | 23.767 | 23.793 | 23.810 | 42.75 | ° C. |
| 1.6440 | 1.6458 | 1.6470 | ms | 23.718 | 23.744 | 23.761 | 42.80 | ° C. |
| 1.6406 | 1.6424 | 1.6436 | ms | 23.669 | 23.695 | 23.712 | 42.85 | ° C. |
| 1.6372 | 1.6390 | 1.6402 | ms | 23.620 | 23.646 | 23.663 | 42.90 | ° C. |
| 1.6339 | 1.6357 | 1.6368 | ms | 23.572 | 23.598 | 23.615 | 42.95 | ° C. |
| 1.6305 | 1.6323 | 1.6335 | ms | 23.523 | 23.549 | 23.566 | 43.00 | ° C. |

Understandably, the above table is only an explanation for one scenario. Meanwhile, the above table contains data obtained by testing in a specific scenario, and the data may be diverse due to factors such as a testing or application environment, device characteristics, or circuit characteristics. In a practical application, a comparison table that matches the scenario can be obtained after specific tests.

Further, the calibration unit 110 includes a first resistor R1.

A first terminal of the first resistor R1 is coupled to a second port GPO2 of the processing module 400, and a second terminal of the first resistor R1 is coupled to the first terminal of the first capacitor C1.

The first resistor R1 is a non-temperature-sensitive resistor RT.

The first resistor R1 is coupled in series between the charging module 100 and the second port GPO2 of the processing module 400; when the second port GPO2 is powered on, the voltage at the second port GPO2 charges the charging module 100 through the first resistor R1; and when the second port GPO2 is grounded, the charging module 100 is discharged through the first resistor R1.

Understandably, because the first resistor R1 is a non-temperature-sensitive resistor RT, that is, the resistance value of the first resistor R1 does not change with temperature, the charging rate is constant when the voltage value output from the first port GPIO1 is constant and the capacitance value of the first capacitor C1 is constant.

Further, the timing module 300 includes an operational amplifier U1, a second resistor R2, a third resistor R3, and a fourth resistor R4.

An inverting input terminal of the operational amplifier U1 is coupled to the charging module 100, a non-inverting input terminal of the operational amplifier U1 is grounded through the second resistor R2, the non-inverting input terminal of the operational amplifier U1 is also coupled to a third port GPO3 of the processing module 400 through the third resistor R3, and an output terminal of the operational amplifier U1 serves as the output terminal of the timing module 300; a first terminal of the fourth resistor R4 is coupled to the output terminal of the operational amplifier U1, and a second terminal of the fourth resistor R4 is coupled between the second resistor R2 and the third resistor R3.

When the non-inverting input terminal voltage of the operational amplifier U1 is greater than the inverting input terminal voltage, the operational amplifier U1 outputs a high level to the processing module 400. When the non-inverting input terminal voltage of the operational amplifier U1 is less than or equal to the inverting input terminal voltage, the operational amplifier U1 outputs a low level to the processing module 400.

The voltage output from the third port GPO3 is divided by the second resistor R2 and the third resistor R3 and then reaches the non-inverting input terminal of the operational amplifier U1; the non-inverting input terminal voltage of the operational amplifier U1 can be determined by setting the ratio of the second resistor R2 to the third resistor R3; and the specific resistance values of the second resistor R2 and the third resistor R3 can be set based on actual application needs.

The fourth resistor R4 is a pull-up resistor configured to maintain the signal output to the processing module 400 as a high-level signal when the operational amplifier U1 does not output a low-level signal. Understandably, the second terminal of the fourth resistor R4 may be coupled to other voltage source terminals.

The timing module 300 further includes a fourth capacitor and a fifth resistor R5, the fifth resistor R5 is coupled in series between the third port GPO3 of the processing module 400 and the third resistor R3, a first terminal of the fourth capacitor is coupled between the fifth resistor R5 and the third resistor R3, and a second terminal of the fourth capacitor is grounded; the fourth capacitor and the fifth resistor R5 constitute an RC filter circuit, which can filter out interference noise from the voltage input from the third port GPO3.

Understandably, in this embodiment, the first time signal output to the processing module 400 is used for indicating the duration when the voltage of the first capacitor C1 rises from 0 to the non-inverting input terminal voltage of the operational amplifier U1. That is, the first time signal indicates a fixed voltage change of the first capacitor C1, and the charging rate is determined by detecting the charging time. In other embodiments, the timing module 300 may alternatively be configured as a voltage collection circuit, a collection terminal of the voltage collection circuit is coupled to the first terminal of the first capacitor C1, and an output terminal of the voltage collection circuit is coupled to the processing module 400. The processing module 400 activates a timer to start timing when the first capacitor C1 starts charging, and continuously obtains collected voltage values output by the voltage collection circuit. In this case, the charging time can be obtained through the timer, the real-time voltage value of the first capacitor C1 can be obtained through the voltage collection circuit, and the charging rate can be calculated by the charging time and the real-time voltage value. The specific structure of the voltage collection circuit can be configured based on practical application needs, and is not limited here.

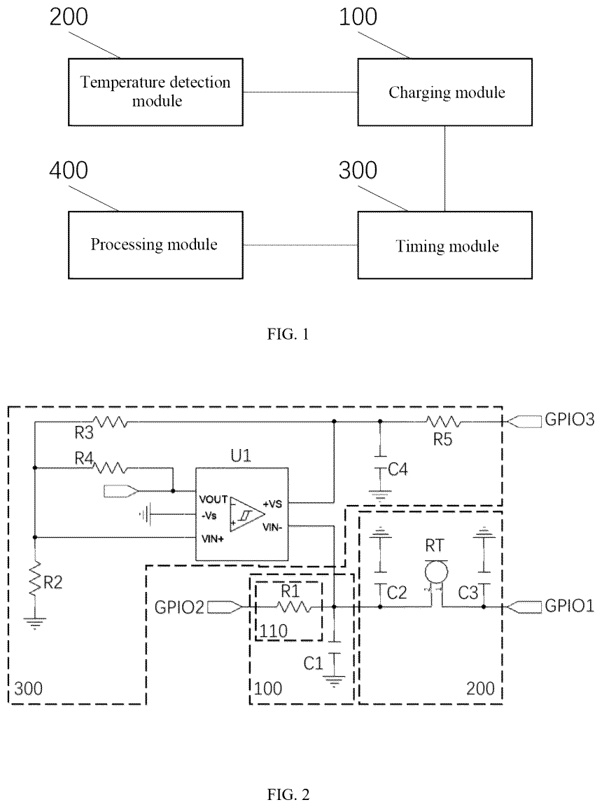

The present application further provides a temperature detection method for implementing the aforementioned temperature detection circuit. Refer to FIG. 1, which is a schematic flowchart of a first embodiment of a temperature detection circuit in the present invention. The temperature detection method includes:
sending a first charging signal to the temperature detection module, so that the temperature detection module charges the charging module;
receiving a first time signal sent by the timing module, where the first time signal is generated based on a charging rate of the temperature detection module, and the charging rate is obtained by detecting the voltage of the charging module; and
determining a target temperature value through the first time signal.

The first charging signal is a signal indicating that the temperature detection module charges the charging module.

Notably, when the body temperature is detected, target temperature values corresponding to different temperature measurement parts are different, such as armpit, forehead, ear canal, oral cavity, and anal testing. To unify the reference levels of the output target temperature values, the target temperature values obtained from the different temperature measurement parts are compensated. Specifically, temperature values of different parts can be detected in advance and compared with standard body temperature values to obtain compensation values of the parts. Before user's body temperature is detected, a temperature measurement part can be selected; and after a target temperature value is determined, the target temperature value is compensated based on the corresponding compensation value of the part to obtain a finally output target temperature value.

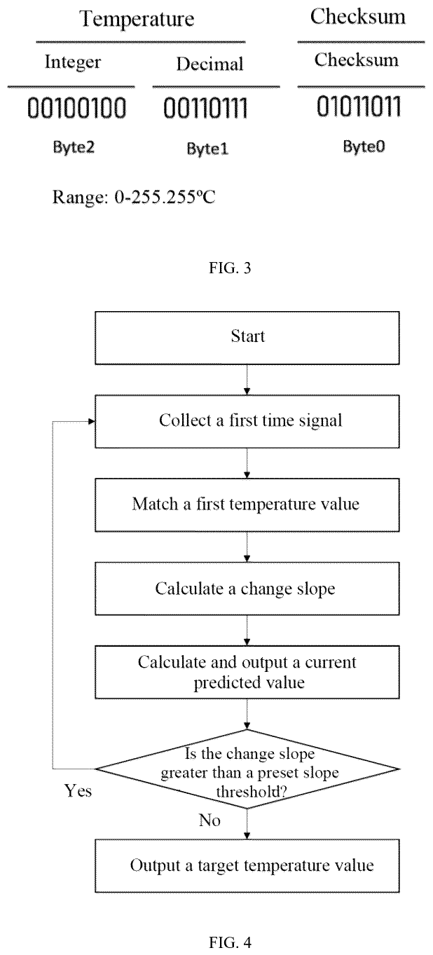

When the target temperature value is output, the target temperature value can be converted into a 3-byte 8-bit binary valid signal, which can be quickly applied to various temperature control products and platforms to reduce development costs. Refer to FIG. 3, which is a schematic diagram of an output format of a target temperature value in the temperature detection method of the present invention. 8 bits of the first byte indicate an integer of the target temperature value, 8 bits of the second byte indicate a decimal of the target temperature value, and 8 bits of the third byte indicate a checksum. An output range of the target temperature value is 0-255.255° C. When the sum of the first byte and the second byte is the third byte, it indicates that the target temperature value is correct. For example, the target temperature value is 36.55° C., and the sum of the first byte and the second byte is 36+55=91. If the checksum is 91, it is considered that the target temperature value is correct.

Undoubtedly, because the temperature detection method of this embodiment adopts the technical solution of the aforementioned temperature detection circuit, the temperature detection method has all the beneficial effects of the temperature detection circuit.

Further, with reference to FIG. 4, the step of receiving a first time signal sent by the timing module includes:
activating a timer for timing when sending the first charging signal to the temperature detection module;
stopping the timer when receiving a low-level signal sent by the operational amplifier, to obtain timing duration; and
designating the timing duration as the first time signal.

When the first charging signal is sent to the temperature detection module, the temperature detection module starts charging the first capacitor, and the timer starts timing synchronously. As the first capacitor is continually charged, the voltage of the first capacitor rises. When the voltage of the first capacitor is less than the non-inverting input terminal voltage of the operational amplifier, the operational amplifier outputs a high-level signal. When the voltage of the first capacitor rises to the non-inverting input terminal voltage of the operational amplifier, the operational amplifier outputs a low-level signal, the timer stops timing, and the timing duration of the timer is the first time signal.

In practical applications, a first time when the first charging signal is sent to the temperature detection module and a second time when the low-level signal sent by the operational amplifier is received may be obtained, and the difference between the first time and the second time is designated as the timing duration.

Further, the step of determining a target temperature value through the first time signal includes:
matching a first temperature value corresponding to the first time signal;
obtaining a second temperature value and calculating a change slope between the second temperature value and the first temperature value, where the second temperature value is the first temperature value matched last time;
determining whether the change slope is less than or equal to a preset slope threshold; and
designating the first temperature value as the target temperature value if the change slope is less than or equal to the preset slope threshold.

The first temperature value is a temperature value corresponding to the first time signal. Understandably, based on the aforementioned description of the temperature detection circuit, when the capacitance of the first capacitor is constant, the corresponding relationship between the resistance value of the temperature-sensitive resistor and the timing duration corresponding to the first time signal is determined. In practical applications, after the settings of the temperature detection circuit are completed, different ambient temperatures can be simulated, and the resistance value, timing duration, and charging rate of the temperature-sensitive resistor are detected for different temperature values to obtain a corresponding relation table; and then a temperature value corresponding to a time signal is obtained by matching based on the relation table.

Understandably, the resistance value of the temperature-sensitive resistor changes continuously, that is, the resistance value of the temperature-sensitive resistor needs to change continuously for a period of time, and ultimately corresponds to the target temperature value. Therefore, the charging rate of the first capacitor needs to be detected continuously. After the detected charging rate is stable, the final target temperature value is determined.

The second temperature value is a temperature value determined last time. The difference between the first temperature value and the second temperature value, namely, the change slope, can reflect a temperature change within the time of two detections. Specifically, the change slope is:

$$K = \frac{T 1 - T 2}{t}$$

where K is the change slope, T1 is the first temperature value, T2 is the second temperature value, and t is the duration between the time when the first temperature value is determined and the time when the second temperature value is determined.

The preset slope threshold indicates a minimum degree of stable change in the resistance value of the temperature-sensitive resistor. When the change slope is less than or equal to the preset slope threshold, it is considered that the resistance value of the temperature-sensitive resistor is stable, and the first temperature value determined this time is designated as the final target temperature value.

A ground signal is output to the first port to discharge the first capacitor if the change slope is greater than the preset slope threshold.

The step of sending a first charging signal to the temperature detection module is performed after the discharging of the first capacitor is completed.

When the change slope is greater than the preset slope threshold, it is considered that the resistance value of the temperature-sensitive resistor is not yet stable, the current resistance value is still changing, and the target temperature value cannot be determined. Therefore, the first capacitor is discharged. After the discharging is completed, the current first temperature value is designated as the second temperature value, and the aforementioned first temperature value is re-determined.

Further, performing the step of sending a first charging signal to the temperature detection module after the discharging of the first capacitor is completed includes:
matching a delay time corresponding to the change slope, where the larger the change slope, the shorter the delay time; and
performing the step of sending a first charging signal to the temperature detection module after the discharging of the first capacitor is completed and the discharging completion time reaches the delay time.

In order to reduce power consumption, in this embodiment, a higher detection frequency is set in the early stage of temperature detection, and a lower detection frequency is set in the later stage of temperature detection. Understandably, in the early stage of temperature detection, the change slope is larger, that is, the temperature changes quickly, so the higher detection frequency is set to track the temperature; in the later stage, the change slope is smaller and the temperature change is slower, so the detection frequency is reduced to save energy consumption.

The delay time is used for setting the detection frequency; the longer the delay time, the lower the detection frequency; the shorter the delay time, the higher the detection frequency. Therefore, negatively correlating the delay time with the change slope can achieve a higher detection frequency when the change slope is larger and a lower detection frequency when the change slope is smaller.

Understandably, because the change slope corresponds to the difference between the first temperature value and the second temperature value, the change slope can also be replaced with the temperature difference between the first temperature value and the second temperature value.

In practical applications, for the stability of detection, a plurality of delay time can be set, so as to determine the delay time matching the change slope. For example, the delay time is set to 200 ms and 1 S; the preset delay slope is 0.5; when the change slope is greater than 0.5, the corresponding delay time is 200 ms; and when the change slope is less than or equal to 0.5, the corresponding delay time is 1 S.

Further, if the change slope is greater than the preset slope threshold, the method further includes:
matching a predicted temperature compensation value corresponding to the slope change;
designating a sum of the predicted temperature compensation value and the first temperature value as a current predicted value; and
outputting the current predicted value.

Understandably, in practical applications, temperature values still need to be output in the temperature rise stage, such as uploaded to an upper computer or displayed. When the change slope is greater than the preset slope threshold, it is considered that the target temperature value cannot be determined currently. In order to make the output temperature value closer to the target temperature value, the first temperature value is compensated, so that the currently output temperature value, namely, the current predicted value, is closer to the final target temperature value.

Understandably, the larger the change slope, the greater the difference from the target temperature value, so the larger the value that needs to be compensated. The relationship between the predicted temperature compensation value and the change slope can be set based on actual application scenarios. For example, if K>2, the predicted temperature compensation value is 1.5; if 1<K≤2, the predicted temperature compensation value is 1; if 0.5<K≤1, the predicted temperature compensation value is 0.5; if 0.25<K≤0.5, the predicted temperature compensation value is 0.25; if K=0.25, T=1, where the preset slope threshold is 0.25. It should be noted that the aforementioned change slope and predicted temperature compensation value are explanations for temperature rise, and can be analogized for temperature drop.

Further, before the step of sending a first charging signal to the temperature detection module, the method further includes:
sending a second charging signal to the first resistor to charge the first capacitor;
receiving a second time signal sent by the timing module;
determining whether the second time signal is consistent with a preset calibration time; and
performing a warning operation if the second time signal is inconsistent with the preset calibration time; or performing the step of sending a first charging signal to the temperature detection module if the second time signal is consistent with the preset calibration time.

The second charging signal is a signal indicating the first resistor to charge the charging module;

The second time signal indicates the time when the voltage of the first capacitor rises from 0 to the voltage at the non-inverting input terminal of the operational amplifier during charging by the first resistor.

Based on the aforementioned description of the temperature detection circuit, it can be seen that the first resistor is a non-temperature-sensitive resistor. Therefore, when the first capacitor is normal, the corresponding second time signal should be consistent, that is, be the preset calibration time; when the second time signal is inconsistent with the preset calibration time, it is considered that the capacitor is faulty and a warning operation is required to prompt the user that any detection cannot be implemented currently or the detection result is inaccurate; and when the second time signal is consistent with the preset calibration time, subsequent operations can be performed. Notably, because the capacitor is currently in a charged state, the capacitor needs to be discharged until it is empty, and then the first charging signal is sent to the temperature detection module.

Further, when the second time signal is inconsistent with the preset calibration time, a time difference between the second time signal and the preset calibration time is calculated, a current capacitance value of the first capacitor is calculated based on the time difference, and a compensation temperature value is calculated based on the current capacitance value of the first capacitor and an initial capacitance value of the first capacitor; after the target temperature value is determined, the target temperature value is compensated based on the temperature compensation value to obtain a final compensation target temperature value.

This embodiment can calibrate the state of the first capacitor to avoid affecting the accuracy of detection due to the fault of the first capacitor.

Notably, in order to simplify the description, the aforementioned method embodiments are all described as combinations of a series of operations. However, those skilled in the art should be aware that the present application is not limited by the order of the described operations, as some steps may be performed in other orders or simultaneously according to the present application. In addition, those skilled in the art should also be aware that all the embodiments in the description are preferred embodiments, and the involved operations and modules are not necessarily mandatory to the present application.

Through the description of the above implementations, those skilled in the art can clearly understand that the method according to the above embodiments can be implemented by software in addition to a necessary universal hardware platform or by hardware only. In most cases, the former is a more preferred implementation. Based on such an understanding, the technical solutions of the present application essentially, or the part contributing to the prior art may be implemented in a form of a software product. The software product is stored in a storage medium (such as ROM/RAM, a magnetic disk, or an optical disc), and includes instructions for instructing a terminal device (which may be a mobile phone, a computer, a server, a network device, or the like) to perform the method described in the embodiments of the present application.

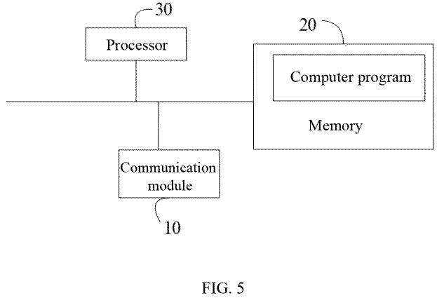

With reference to FIG. 5, the present application further provides an electronic device. In terms of a hardware structure, the electronic device may include components, such as a communication module 10, a memory 20, and a processor 30. In the electronic device, the processor 30 is coupled to the memory 20 and the communication module 10 respectively, the memory 20 stores a computer program, and the computer program is executed by the processor 30 to implement the steps of the above method embodiments.

The communication module 10 may be coupled to an external communication device through a network. The communication module 10 may receive a request from the external communication device, or send a request, instructions, and information to the external communication device. The external communication device may be another electronic device, server, or Internet of things device, such as a television.

The memory 20 may be configured to store a software program and various data. The memory 20 may mainly include a program storage area and a data storage area, where the program storage area may store an operating system, an application required for at least one function (such as sending a first charging signal to the temperature detection module), etc.; and the data storage area may include a database and store data or information created based on the usage of the system. In addition, the memory 20 may include a high-speed random access memory, or may include a non-volatile memory, such as at least one magnetic disk storage device, a flash memory device, or other volatile solid-state storage devices.

The processor 30 is a control center of the electronic device, connects various parts of the entire electronic device using various interfaces and lines, and executes various functions and processing data of the electronic device by running or executing the software program and/or modules stored in the memory 20 and calling the data stored in the memory 20, so as to monitor the overall electronic device. The processor 30 may include one or more processing units. Optionally, the processor 30 may integrate an application processor and a modem processor, where the application processor mainly processes operating systems, user interfaces, applications, and the like, and the modem processor mainly processes wireless communication. It may be understood that the modem processor may alternatively not be integrated into the processor 30.

Although not shown in FIG. 5, the aforementioned electronic device may further include a circuit control module, which is coupled to a power supply to ensure the normal operation of other components. Those skilled in the art can understand that the electronic device structure shown in FIG. 5 does not constitute a limitation on the electronic device, and may include more or fewer components than those shown in the figure, or a combination of some components, or components disposed differently.

The present invention further provides a computer-readable storage medium, storing a computer program. The computer-readable storage medium may be the memory 20 in the electronic device of FIG. 5, or at least one of an ROM (Read-Only Memory)/RAM (Random Access Memory), a magnetic disk, and an optical disk. The computer-readable storage medium includes instructions for instructing a terminal device (which may be a television, a car, a mobile phone, a computer, a server, a terminal, or a network device) with a processor to execute the methods in various embodiments of the present invention.

In the present invention, the terms “first”, “second”, “third”, “fourth”, and “fifth” are only used for descriptive purposes and should not be understood as indicating or implying relative importance. Those of ordinary skill in the art can understand the specific meanings of the above terms in the present invention according to specific circumstances.

In the description, the reference to the terms “one embodiment”, “some embodiments”, “example”, “specific example”, or “some examples” means that the specific features, structures, materials, or characteristics described in conjunction with the embodiments or examples are included in at least one embodiment or example of the present invention. In the description, the schematic expressions of the above terms do not necessarily refer to the same embodiments or examples. Moreover, the described specific features, structures, materials or characteristics can be combined appropriately in one or more embodiments or examples. In addition, those skilled in the art may incorporate and combine different embodiments or examples and features of different embodiments or examples in the description on a non-contradictory basis.

Although the embodiments of the present invention are shown and described above, the scope of protection of the present invention is not limited thereto. It should be understood that the above embodiments are exemplary and should not be construed as limitations of the present invention. Those of ordinary skill in the art can make changes, modifications, and substitutions to the above embodiments within the scope of the present invention, and these changes, modifications, and substitutions should be included within the scope of protection of the present invention. Therefore, the scope of protection of the present invention shall be subject to the scope of protection of the claims.

What is claimed is:

1. A temperature detection circuit, comprising a charging module, a temperature detection module, a timing module, and a processing module, wherein the charging module is coupled to detection terminals of the temperature detection module and the timing module respectively, and an output terminal of the timing module is coupled to the processing module, wherein
the temperature detection module is configured to charge the charging module based on a detected temperature;
the timing module is configured to detect the voltage of the charging module to determine a charging rate of the temperature detection module, generate a first time signal corresponding to the charging rate, and send the first time signal to the processing module; and
the processing module is configured to determine a target temperature value through the first time signal.

2. The temperature detection circuit according to claim 1, wherein the temperature detection module comprises a temperature-sensitive resistor, a first terminal of the temperature-sensitive resistor is coupled to a first port of the processing module, and a second terminal of the temperature-sensitive resistor is coupled to the charging module.

3. The temperature detection circuit according to claim 1, wherein the charging module comprises a calibration unit and a first capacitor, a first terminal of the first capacitor is coupled to the detection terminals of the calibration unit, the temperature detection module, and the timing module respectively, and a second terminal of the first capacitor is grounded; and
the calibration unit is configured to charge the first capacitor at a preset charging rate.

4. The temperature detection circuit according to claim 3, wherein the calibration unit comprises a first resistor, wherein
a first terminal of the first resistor is coupled to a second port of the processing module, and a second terminal of the first resistor is coupled to the first terminal of the first capacitor; and
the first resistor is a non-temperature-sensitive resistor.

5. The temperature detection circuit according to claim 1, wherein the timing module comprises an operational amplifier, a second resistor, a third resistor, and a fourth resistor, wherein
an inverting input terminal of the operational amplifier is coupled to the charging module, a non-inverting input terminal of the operational amplifier is grounded through the second resistor, the non-inverting input terminal of the operational amplifier is also coupled to a third port of the processing module through the third resistor, and an output terminal of the operational amplifier serves as the output terminal of the timing module; a first terminal of the fourth resistor is coupled to the output terminal of the operational amplifier, and a second terminal of the fourth resistor is coupled between the second resistor and the third resistor.

6. A temperature detection method, wherein the temperature detection method is applied to a temperature detection circuit, and the temperature detection circuit comprises a charging module, a temperature detection module, a timing module, and a processing module, wherein the charging module is coupled to detection terminals of the temperature detection module and the timing module respectively, and an output terminal of the timing module is coupled to the processing module, wherein the temperature detection module is configured to charge the charging module based on a detected temperature; the timing module is configured to detect the voltage of the charging module to determine a charging rate of the temperature detection module, generate a first time signal corresponding to the charging rate, and send the first time signal to the processing module; and the processing module is configured to determine a target temperature value through the first time signal;
the temperature detection method comprises:
sending a first charging signal to the temperature detection module, so that the temperature detection module charges the charging module;
receiving a first time signal sent by the timing module, wherein the first time signal is generated based on a charging rate of the temperature detection module, and the charging rate is obtained by detecting the voltage of the charging module; and
determining a target temperature value through the first time signal.

7. The temperature detection method according to claim 6, wherein the step of receiving a first time signal sent by the timing module comprises:
activating a timer for timing when sending the first charging signal to the temperature detection module;
stopping the timer when receiving a low-level signal sent by the operational amplifier, to obtain timing duration; and
designating the timing duration as the first time signal.

8. The temperature detection method according to claim 6, wherein the step of determining a target temperature value through the first time signal comprises:
matching a first temperature value corresponding to the first time signal;
obtaining a second temperature value and calculating a change slope between the second temperature value and the first temperature value, wherein the second temperature value is the first temperature value matched last time;
determining whether the change slope is less than or equal to a preset slope threshold; and
designating the first temperature value as the target temperature value if the change slope is less than or equal to the preset slope threshold.

9. The temperature detection method according to claim 8, wherein after the step of determining whether the change slope is less than a preset slope threshold, the method comprises:
outputting a ground signal to the first port to discharge the first capacitor if the change slope is greater than the preset slope threshold; and
performing the step of sending a first charging signal to the temperature detection module after the discharging of the first capacitor is completed.

10. The temperature detection method according to claim 9, wherein the performing the step of sending a first charging signal to the temperature detection module after the discharging of the first capacitor is completed comprises:
matching a delay time corresponding to the change slope, wherein the larger the change slope, the shorter the delay time; and
performing the step of sending a first charging signal to the temperature detection module after the discharging of the first capacitor is completed and the discharging completion time reaches the delay time.

11. The temperature detection method according to claim 9, wherein if the change slope is greater than the preset slope threshold, the method further comprises:
matching a predicted temperature compensation value corresponding to the slope change;
designating a sum of the predicted temperature compensation value and the first temperature value as a current predicted value; and
outputting the current predicted value.

12. The temperature detection method according to claim 6, wherein before the step of sending a first charging signal to the temperature detection module, the method further comprises:
sending a second charging signal to the first resistor to charge the first capacitor;
receiving a second time signal sent by the timing module;
determining whether the second time signal is consistent with a preset calibration time; and
performing a warning operation if the second time signal is inconsistent with the preset calibration time; or
performing the step of sending a first charging signal to the temperature detection module if the second time signal is consistent with the preset calibration time.

13. An electronic device, comprising a memory, a processor, and a computer program stored in the memory and executable on the processor, wherein the computer program, when executed by the processor, implements a temperature detection method, and the temperature detection method comprises: sending a first charging signal to a temperature detection module, so that the temperature detection module charges a charging module; receiving a first time signal sent by a timing module, wherein the first time signal is generated based on a charging rate of the temperature detection module, and the charging rate is obtained by detecting the voltage of the charging module; and determining a target temperature value through the first time signal.

14. The electronic device of claim 13, wherein the step of receiving a first time signal sent by the timing module comprises:
activating a timer for timing when sending the first charging signal to the temperature detection module;
stopping the timer when receiving a low-level signal sent by the operational amplifier, to obtain timing duration; and
designating the timing duration as the first time signal.

15. The electronic device of claim 13, wherein the step of determining a target temperature value through the first time signal comprises:
matching a first temperature value corresponding to the first time signal;
obtaining a second temperature value and calculating a change slope between the second temperature value and the first temperature value, wherein the second temperature value is the first temperature value matched last time;
determining whether the change slope is less than or equal to a preset slope threshold; and
designating the first temperature value as the target temperature value if the change slope is less than or equal to the preset slope threshold.

16. The electronic device of claim 15, wherein after the step of determining whether the change slope is less than a preset slope threshold, the method comprises:
outputting a ground signal to the first port to discharge the first capacitor if the change slope is greater than the preset slope threshold; and
performing the step of sending a first charging signal to the temperature detection module after the discharging of the first capacitor is completed.

17. The electronic device of claim 16, wherein the performing the step of sending a first charging signal to the temperature detection module after the discharging of the first capacitor is completed comprises:
matching a delay time corresponding to the change slope, wherein the larger the change slope, the shorter the delay time; and
performing the step of sending a first charging signal to the temperature detection module after the discharging of the first capacitor is completed and the discharging completion time reaches the delay time.

18. The electronic device of claim 16, wherein if the change slope is greater than the preset slope threshold, the method further comprises:
matching a predicted temperature compensation value corresponding to the slope change;
designating a sum of the predicted temperature compensation value and the first temperature value as a current predicted value; and
outputting the current predicted value.

19. The electronic device of claim 13, wherein before the step of sending a first charging signal to the temperature detection module, the method further comprises:
sending a second charging signal to the first resistor to charge the first capacitor;
receiving a second time signal sent by the timing module;
determining whether the second time signal is consistent with a preset calibration time; and
performing a warning operation if the second time signal is inconsistent with the preset calibration time; or
performing the step of sending a first charging signal to the temperature detection module if the second time signal is consistent with the preset calibration time.

20. A computer-readable storage medium, storing a non-transitory computer program that, when executed by a processor, implements a temperature detection method, wherein the temperature detection method comprises: sending a first charging signal to a temperature detection module, so that the temperature detection module charges a charging module; receiving a first time signal sent by a timing module, wherein the first time signal is generated based on a charging rate of the temperature detection module, and the charging rate is obtained by detecting the voltage of the charging module; and determining a target temperature value through the first time signal.
